(19) United States
(12) Patent Application Publication
(10) Pub. No.: US 2010/0328913 A1
(43) Pub. Date: Dec. 30, 2010

(54) METHOD FOR THE PRODUCING AN ELECTRONIC SUBASSEMBLY, AS WELL AS ELECTRONIC SUBASSEMBLY

(76) Inventors: Andreas Kugler, Alfdorf (DE); Karl-Friederich Becker, Berlin (DE); Gerhard Liebing, Stuttgart (DE)

Correspondence Address: KENYON & KENYON LLP, ONE BROADWAY, NEW YORK, NY, 10004, US

(21) Appl. No.: 12/791,565

(22) Filed: Jun. 1, 2010

Related U.S. Application Data
(63) Continuation of application No. 12/450,569, now abandoned.

(30) Foreign Application Priority Data
Mar. 30, 2007 (DE) DE 102007015819.1

(51) Int. Cl. H05K 1/18; H05K 3/30; H05K 3/10

(52) U.S. Cl. 361/761; 29/841; 29/846

(57) ABSTRACT

In a method for producing an electronic subassembly, at least one electronic component is mounted on an insulating layer of a conductive foil in a first step, the active side of the electronic component pointing in the direction of the conductive foil. In a second step, the conductive foil having the at least one electronic component mounted thereon is laminated to a circuit board substrate, the at least one electronic component pointing in the direction of the circuit board substrate. Finally, circuit tracks are developed by patterning the conductive foil, and the at least one electronic component is contacted.

### BACKGROUND OF THE INVENTION

1. Field of the Invention

The present invention relates to a method for producing an electronic subassembly including at least one electronic component, and also relates to an electronic subassembly including an electronic component.

2. Description of Related Art

To permit the encapsulation of electronic components used in electronic subassemblies on circuit boards and to increase the space utilization on the electronic circuit board, it is known to accommodate the electronic components within the circuit board. This protects the electronic components. From U.S. Pat. No. 6,512,182, for example, it is known to cut receptacles into a circuit board substrate, into which the electronic components are then placed. Once the electronic components have been inserted the receptacles are filled, then smoothed and laminated over. The embedding of the electronic components makes it possible to achieve a flat surface of the electronic subassembly.

One disadvantage of this subassembly is that receptacles into which the electronic components are placed are cut into the circuit board substrate first. This makes the precise positioning of the electronic components quite difficult.

From published German patent document DE-A 10 2005 003 125, a method for producing an electric circuit is known; the circuit has electric components, which are mechanically interconnected through a casting compound. Provided on at least one side of the casting compound is at least one layer of circuit tracks by which the components are electrically connected to each other. To produce the circuit, the components are mounted on a carrier foil and then encapsulated by a casting compound. The carrier foil is subsequently removed, and on the side on which the components were joined to the carrier foil, one or more layers of circuit tracks are applied, which electrically connect the components to each other.

One disadvantage of this method is that the carrier foil must be removed completely in order to obtain a functioning interconnection of the electric circuit.

### BRIEF SUMMARY OF THE INVENTION

The method of the present invention for producing an electronic subassembly including at least one electronic component encompasses the following steps:
(a) Mounting the at least one electronic component on the insulating layer of the conductive carrier foil, the active side of the component pointing in the direction of the foil;
(b) Laminating the conductive carrier foil having the at least one electronic component mounted thereon onto a circuit board substrate, the at least one electronic component pointing in the direction of the circuit board substrate;
(c) Developing circuit tracks by patterning the conductive carrier foil, and contacting the at least one electronic component.

Affixing the at least one electronic component to the insulating layer of the conductive carrier foil makes it possible to position the electronic components precisely. When the conductive carrier foil having the at least one electronic component affixed thereon is subsequently laminated to a printed circuit board, the at least one electronic component pointing in the direction of the printed circuit board, the at least one electronic component is enclosed by the printed circuit board. This completely encapsulates the component.

The required circuit tracks are produced in an uncomplicated manner by patterning the conductive carrier foil. This enables a rapid and cost-effective production of the electronic subassembly.

In one example embodiment, the at least one electronic component is enclosed by a polymer mass once it has been fixed in place on the conductive carrier foil. Enclosing the at least one electronic component by the polymer mass provides additional protection of the component. The risk of damage is considerably reduced in this way, even for sensitive components.

For instance, the polymer mass by which the at least one electronic component is enclosed is a low pressure compression mass, e.g., an epoxy low pressure compression mass. The low-pressure compression mass is applied using an injection molding process, for example. Place holders for thicker dielectrics, for example, may be reserved in the polymer mass in addition. However, they may also be injection-molded in the form of inserts when injection-molding the at least one electronic component.

The at least one electronic component may be fixed in place by adhesive bonding. To this end, the conductive carrier foil preferably includes an adhesive layer. Preferably, the adhesive layer simultaneously forms the insulating layer. The conductive carrier foil is a self-adhesive, conductive carrier foil, for instance. The adhesive mounting may be performed by heat and pressure processes. This also includes a heat bonding process, for example.

The conductive carrier foil used is a copper foil, for instance, as it is also known as RCC material from circuit board technology. Other suitable foils are LCP foils or FEP foils, for example. In addition to copper, aluminum, for example, is a suitable metal as well.

In one example embodiment, alignment marks are introduced in the conductive carrier foil prior to mounting the at least one electronic component on the conductive foil in step (a). The alignment marks are holes or blind holes, for example, having any desired cross-section. They may be introduced into the conductive carrier foil by etching, stamping or drilling, for instance. The alignment marks are made on the side of the conductive carrier foil that lies opposite the at least one electronic component. Because of the alignment marks, it is possible to determine the precise position of the at least one electronic component even after the at least one electronic component has been encased in the polymer mass or after the conductive carrier foil has been laminated to the circuit board substrate. This is necessary for the contacting of the at least one electronic component. As an alternative, components that are situated on the conductive foil, for instance, also are suitable as alignment marks. At the locations where the components are situated, the conductive foil is preferably exposed by drilling or is x-rayed in order to detect the components. In addition, the alignment marks may naturally also have any other form known to one skilled in the art.

It is preferred if holes are introduced at the positions where the at least one electronic component is to be electrically contacted with the conductive carrier foil. For example, the holes are metal-coated for the contacting of the conductive carrier foil having the at least one electronic component. The holes are introduced by laser-drilling, for example. The positions at which the holes are introduced are determined with the aid of the alignment marks.

The metal-coating of the holes to establish contact between the electronic component and the conductive carrier foil is implemented according to methods known to one skilled in the art. For example, the metal-coating may be implemented by currentless metal deposition. The currentless metal deposition is a conventional method used in the production of printed circuit boards. The metal-coating of the holes is preferably implemented using copper.

Additional circuit tracks may, for instance, be applied by mounting additional layers provided with circuit tracks on the conductive carrier foil patterned in step (c). To this end, a dielectric, which covers the circuit tracks developed in step (c), is preferably applied first. This simultaneously insulates the circuit tracks so that no undesired electric contact takes place with the circuit tracks of the layer applied subsequently. Additional circuit tracks are then affixed on the dielectric using methods known to one skilled in the art. As an alternative, the additional layers, which include the circuit tracks, may also be produced by applying additional conductive foils on the first layer and then patterning the foil in order to develop circuit tracks.

To dissipate heat generated while the electronic subassembly is operating, it is preferred if the at least one electronic component is contacted by a metal core on the side pointing away from the conductive carrier foil once the conductive carrier foil has been laminated to the circuit board substrate in step (b), so that the metal core is also integrated in the circuit board after lamination to the circuit board substrate. During operation the electronic component releases heat to the metal core, via which it is then able to be dissipated to the outside.

The advantage of the method of the present invention is that the encasing of the at least one electronic component by the polymer mass, or the embedding of the electronic component in the circuit board substrate, provides a cost-effective encapsulation of passive and active electronic components. In addition, the electronic subassembly is very reliable because of the complete encapsulation of sensitive components. An additional advantage of the encapsulation is that it allows for a height adjustment if components of different heights are used.

Furthermore, the method according to the present invention avoids risky mixed techniques in the production, such as soldering, adhesive bonding and wire bonding, for example. When the electronic subassembly is used in high-frequency technology, i.e., if the electronic component is a high-frequency component, then reproducible high-frequency transitions are achieved through the planar base structure obtained by the method according to the present invention.

Moreover, the method according to the present invention makes it possible to integrate possibly required heat sinks on power semiconductors. For instance, they may contact the electronic component on the side facing away from the conductive carrier foil. As an alternative, for example, it is also possible to embed them in the polymer mass by which the at least one electronic component is enclosed.

Furthermore, the method of the present invention makes it possible to achieve cost-effective wiring and encapsulation on many modules simultaneously.

In addition, the present invention relates to an electronic subassembly, which includes at least one electronic component connected to a circuit track structure on a circuit board, the at least one electronic component being embedded in the circuit board and the circuit track structure being situated at the surface of the circuit board. Apart from the cost-effective encapsulation already mentioned earlier and the resulting high reliability, the expensive substrate and packaging technology currently used in the related art is replaced or reduced to one small component. Moreover, with the electronic subassembly according to the present invention, a complete high-frequency circuit is able to be concentrated on one module, including antennas. The electronic subassembly produced according to the present invention is able to be processed further as a standard component.

In one example embodiment, the circuit track structure is implemented in a plurality of layers. This allows for better utilization of the surface of an electronic circuit board. Because of the additional layers the electronic subassembly is able to be fitted with components and contacted in a very confined space.

To provide excellent dissipation of the heat generated during the operation of the electronic subassembly, it is preferred if a metal core with a metal connection to the at least one electronic component is included in the circuit board.

In addition to the at least one electronic component, it is also possible for the electronic subassembly to include one or more mechanical components.

Electronic components used in the method according to the present invention or in the electronic subassembly developed according to the present invention are any electronic components used in circuit board technology and microelectronics and known to one skilled in the art. Also conceivable as mechanical components are any components that are used in circuit board technology.

### BRIEF SUMMARY OF THE SEVERAL VIEWS OF THE DRAWING

FIGS. 1 through 8 show a plurality of steps in the production of a device according to an example embodiment of the present invention.

### DETAILED DESCRIPTION OF THE INVENTION

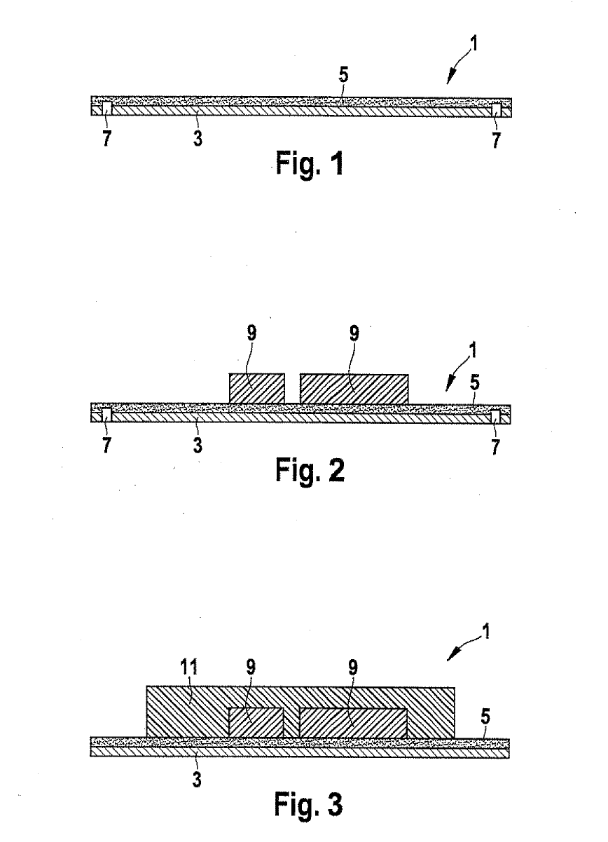

FIG. 1 shows a conductive carrier foil 1, which includes a conductive layer 3 and an insulating layer 5. Preferably, insulating layer 5 is an adhesive layer or a thermoplast on top of which electronic components are mountable. Alignment marks 7 are introduced on the side of conductive carrier foil 1 on which conductive layer 3 is located. For example, alignment marks 7 may be introduced into conductive carrier foil 1 by etching, stamping or drilling, e.g., laser drilling. Furthermore, it is also possible that the alignment marks are components connected to conductive carrier foil 1, which are exposed by drilling or detected by x-ray microscopy. Any other form of alignment marks known to one skilled in the art is possible as well.

Conductive layer 3 preferably is a metal layer. Especially preferred as metal is copper.

In a second step, electronic components 9 are mounted on insulating layer 5. This is illustrated in FIG. 2. In addition to electronic components 9, it is also possible to mount mechanical components on insulating layer 5 of conductive carrier foil 1. Electronic components 9 or mechanical components mounted on insulating layer 5 of conductive carrier foil 1 are conventional components that are used in the construction of circuit boards. These are, for example, chips, processors, high-frequency components, SMD components, antenna modules, heat sinks, MEMS or MOEMS.

The mounting of electronic components 9 or the mechanical components is preferably implemented by adhesive affixation to insulating layer 5. In the process, electronic components 9 are placed on insulating layer 5 of conductive carrier foil 1 in accordance with the ultimately intended layout of electronic components 9 in the electric circuit. It is also possible to place heat sinks on top of individual or on all electronic components 9 in order to ensure increased heat dissipation during operation of electronic components 9. The optionally providable heat sinks are placed on the side of electronic components 9 facing away from conductive carrier foil 1.

In order to achieve an encapsulation of sensitive electronic components 9, it is possible to encase them in a polymer mass 11. This is illustrated in FIG. 3. Polymer mass 11 is an epoxy low pressure molding material, for example. If required, place holders for thicker dielectrics, which are used for antennas or heat sinks, for instance, may be injection-molded in polymer mass 11. The encasing by polymer mass 11 is implemented with the aid of a transfer molding process. The place holders can be developed as recesses or troughs, for instance. In addition to the transfer molding method, however, any other method known to one skilled in the art for encasing electronic components 9 in polymer mass 11 may be utilized as well. Moreover, the encapsulation by polymer mass 11 provides the advantage that it allows for a height adjustment of components 9 having different thicknesses. This is advantageous for the subsequent lamination process. Furthermore, components may be pre-encapsulated on a peel-off foil and then mounted on carrier foil 1 once the foil has been peeled off.

After electronic components 9 have been mounted on conductive carrier foil 1 or—if electronic components 9 are to be encased in polymer mass 11—after electronic components 9 have been encased in polymer mass 11, conductive foil 1 is cut to the size of the circuit board.

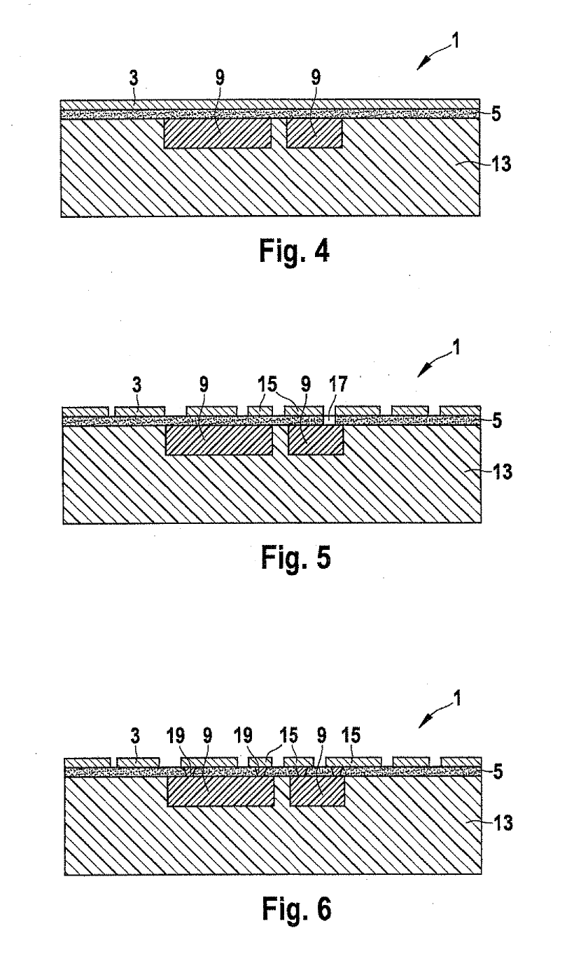

Following the cutting, conductive foil 1 with electronic components 9 mounted thereon and possibly additional components not shown here, is laminated onto a circuit board substrate 13. This is illustrated in FIG. 4. For the variant shown here, conductive foil 1 having electronic components 9 has been laminated onto circuit board substrate 13 without an encapsulation of electronic components 9 by polymer mass 11. However, according to the present invention, the development shown in FIG. 3 in which electronic components 9 are encased by polymer mass 11 is also laminated onto circuit board substrate 13. The laminating is implemented according to methods known to one skilled in the art. According to the present invention, circuit board substrate 13 is laminated to conductive foil 1 in such a way that electronic components 9, or electronic components 9 encased by polymer mass 11, are surrounded by circuit board substrate 13. To this end, circuit board substrate 13 is laminated to conductive foil 1 on the side on which electronic components 9 are mounted as well.

In general, for components 9 whose component thickness is greater than 0.1 mm, a glass fiber-reinforced, cured circuit board material, which is predrilled at the locations of components 9, is first placed on top of the foil for this purpose. A prepreg and possibly an additional cured circuit board material are placed on top of it. Pressure is then applied to this stack in a lamination process. The cured circuit board material is usually an epoxy resin reinforced by glass fiber. However, any other suitable material known to one skilled in the art may be used as well. An epoxy raisin is usually also used as prepreg. However, it has not yet fully cured. By applying pressure and using an increased temperature, the prepreg cures completely and thereby combines with the cured circuit board material. The composite of prepreg and cured circuit board material forms circuit board substrate 13.

After conductive foil 1 including electronic components 9, or including electronic components 9 possibly encased by polymer mass 11, has been laminated onto circuit board substrate 13, holes 17 are cut into carrier foil 1 at the connection points of electronic components 9, carrier foil 1 encompassing conductive layer 3 and insulating layer 5. The correct positioning of holes 17 may be determined by alignment marks 7 introduced at the outset. This makes it possible to produce holes 17 at precisely the positions where the electric connections of electronic components 9 are located.

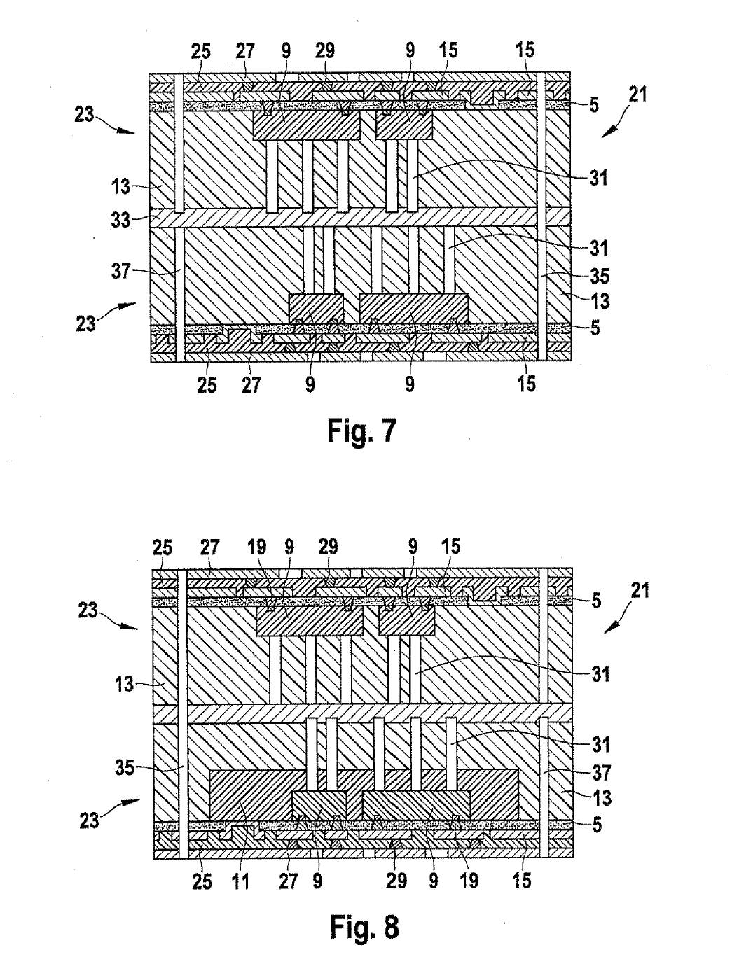

Simultaneously with the introduction of holes 17 for the contacting of electronic components 9 with conductive layer 3 or directly following it, cooling channels 31, as illustrated in FIGS. 7 and 8, are usually drilled into circuit board substrate 13. A laser drilling method, for example, is used for this purpose. If holes 17 are also produced by a laser drilling method, then it is preferred if a second laser is used for cooling channels 31. However, all holes 17 and cooling channels 31 may also be drilled using the same laser.

Electronic components 9 are electrically contacted with conductive layer 3 by way of metal coating. This is illustrated in FIG. 6. Using methods known to one skilled in the art, such as currentless metal deposition, for example, metal 19 is deposited in holes 17 for the metal coating. This metal connects the connections of electronic components 9 to circuit track structure 15. An electronic contact was produced. As a rule, copper is used as metal 19 for the metal coating. For the metallic coating, first a starter metal coat of palladium is usually deposited in a currentless manner. This is followed by a galvanic copper deposition. Metal 19 may assume the form of a sleeve or it may fill holes 17 completely.

After holes 17 have been introduced in conductive foil 1 for the contacting of electronic components 9, and after holes 17 have been metal-coated, conductive layer 3 is patterned as illustrated in FIG. 5. The patterning is implemented by any method known to one skilled in the art. Suitable methods are, for example, etching methods, photoresist methods, laser drilling methods or laser ablation methods.

The patterning of the conductive layer produces the circuit track structures 15 required for the circuit board.

A planar top surface is achieved by embedding electronic components 9 in circuit board substrate 13. This permits simple processing of the surface.

However, it is of course also possible to first produce circuit track structure 15 out of conductive foil 1, and then to introduce and metal-coat the holes in conductive foil 1.

An electronic subassembly 21 is shown in FIG. 7. Electronic subassembly 21 includes two circuit boards 23, which are designed as illustrated in FIG. 6. A dielectric 25 is applied on circuit track structure 15 in order to mount an additional circuit track structure 27. Epoxy resins or FR4 materials, for example, which are known from circuit board technology, are suitable as dielectric 25. The dielectric 25 is applied using the conventional methods known to one skilled in the art. For example, it is possible to apply dielectric 25 by raking, painting, printing, laminating, curtain coating, film-coating, spray-coating or similar methods.

An additional circuit track structure 27 is applied on dielectric 25. For this purpose it is possible first to apply a conductive layer across the entire surface and then to pattern it.

Preferably, it is also possible to apply an additional conductive foil 1 on first circuit track structure 15, and to pattern conductor track structure 27 out of the conductive layer of the second conductive foil. The same methods that are used for patterning conductive layer 3 to form circuit track structure 15 are then preferably utilized for this purpose. Once conductor track structure 27 has been produced, holes 29, through which the contacting of circuit track structure 27 with circuit track structure 15 takes place by way of metal coating, may then be introduced in dielectric 25.

To produce a plurality of conductive layers, patterned so as to form circuit tracks, it is especially preferred if dielectric 25 is laminated first and then a conductive foil. Once dielectric 25 and the conductive foil have been laminated, holes are introduced first, which are then metal-coated in order to electrically connect the conductive foil with the layers lying underneath. A further circuit track structure 27 is subsequently worked out of the conductive foil.

Cooling channels 31 may be introduced in circuit board substrate 13 on the side of electronic components 9 facing away from circuit track structures 15, 27 in order to dissipate heat from electronic components 9. Cooling channels 31 are connectable to a metal core 33. Heat from electronic components 9 is dissipated via metal core 33 and cooling channels 31. Cooling channels 31 are usually connected to metal core 33 via rear-side metal-coating or by alternative connections, in which the inner walls of cooling channels 31 are coated with a metal layer. However, cooling channels 31 may also be completely filled with a metal.

Another option consists of providing heat sinks between metal core 33 and electronic components 9. Metal core 33 may also be designed in such a way that it makes direct contact with electronic components 9.

Preferably, the connection of circuit boards 23 is likewise carried out with the aid of a lamination process, as usual in manufacturing processes of circuit boards.

With the aid of a bore 35, which runs through both circuit boards 23, it is possible to connect circuit track structure 15 of the one circuit board 23 to circuit track structure 27 of second circuit board 23. For instance, the electric contact is realized by metal-coating the wall of bore 35. Using a bore 37, which ends on top of metal core 33, circuit track structure 15, 27 is able to be electrically contacted with metal core 33. This makes it possible to realize a ground contact, for instance. For bore 37, as well, the electric contact is preferably implemented with the aid of metal coating. The metal-coating of bores 35, 37 is produced by currentless or galvanic metal deposition, for instance. As an alternative, however, it is also possible to route a wire through bores 35, 37, for example.

The example embodiment shown in FIG. 8 differs from the example embodiment shown in FIG. 7 in that in one circuit board, the electronic components 9 are not encapsulated in polymer mass 11, and in the case of the second circuit board 23, which is used for electronic subassembly 21, electronic components 9 have been enclosed by polymer mass 11.

In addition to the example embodiments shown in FIGS. 7 and 8, in which two circuit track structures 15, 27 are placed on top of one another in each case, it is also possible to provide more than two circuit track structures on one side. It is likewise possible to develop a different number of circuit track structures 25, 27 on the top surface side and on the bottom surface of electronic subassembly 21.

1-11. (canceled)

12. A method for producing an electronic assembly, comprising:
affixing at least one electronic component on an insulating layer of a conductive film to produce a first sub-assembly, wherein a first, active side of the electronic component is positioned facing the conductive film;
laminating the first sub-assembly onto a printed circuit board carrier, wherein a second side of the electronic component is positioned facing the printed circuit board carrier;
forming at least one conductive strip structure by structuring the conductive film; and
electrically contacting the electronic component to the conductive strip structure.

13. The method as recited in claim 12, wherein after the production of the first sub-assembly, the first sub-assembly is encased by a polymer mass.

14. The method as recited in claim 13, wherein the conductive film includes an adhesive layer, and wherein the adhesive layer forms the insulating layer.

15. The method as recited in claim 14, further comprising:
before affixing the at least one electronic component on the insulating layer of the conductive film, introducing adjustment marks into the conductive film.

16. The method as recited in claim 14, further comprising:
introducing at least one hole into the conductive film at a position where the conductive strip structure is electrically contacted to the electronic component.

17. The method as recited in claim 16, further comprising:
metalizing the at least one hole.

18. The method as recited in claim 14, further comprising:
after forming the at least one conductive strip structure by structuring the conductive film, applying on the structured conductive film at least one other layer containing a conductive strip structure.

19. The method as recited in claim 14, further comprising:
before laminating the first sub-assembly onto the printed circuit board carrier, contacting the second side of the electronic component to a metal core, whereby the metal core is integrated with the printed circuit board carrier upon lamination of the first sub-assembly onto the printed circuit board carrier.

20. An electronic assembly, comprising:
at least one electronic component; and
a printed circuit board having a printed circuit board carrier on a first side and a conductive strip structure on a second side defining an exterior surface of the printed circuit board;
wherein the electronic component is connected to the conductive strip structure, and wherein the electronic component is embedded with the printed circuit board carrier.

21. The assembly as recited in claim 20, wherein the conductive strip structure includes multiple layers.

22. The assembly as recited in claim 21, further comprising:
a metal core contained within the printed circuit board, wherein the metal core is metallically connected to the electronic component.
